(19) United States
(12) Patent Application Publication
(10) Pub. No.: US 2026/0061874 A1
(43) Pub. Date: Mar. 5, 2026

(54) SMART ELECTRICITY SAFETY DETECTION SYSTEM FOR CHARGING STATION

(71) Applicant: E-FANER Tech CO., LTD., Taipei City (TW)

(72) Inventor: WEI-JE CHANG, Taipei City (TW)

(21) Appl. No.: 19/280,156

(22) Filed: Jul. 25, 2025

(30) Foreign Application Priority Data
Sep. 5, 2024 (TW) 113133709

(51) Int. Cl. B60L 53/62; G01R 31/40; G01R 31/52; H02J 7/00

(52) U.S. Cl. CPC B60L 53/62; G01R 31/40; G01R 31/52; H02J 7/663; H02J 7/80

(57) ABSTRACT

A smart electricity safety detection system for a charging station is disclosed, including: a central processor; a first detection unit for detecting and transmitting circuit information of an internal circuit of the charging station to the central processor; a relay connected to a power supply and in signal connection with the central processor and switchable by the central processor to open-circuiting or closed-circuiting; an output port connected to an output terminal of the relay for connection with an electric vehicle; a second detection unit for detecting and transmitting output information of the output port to the central processor for monitoring and analyzing a change rate and a corresponding relationship of the circuit information and the output information, so that when the change rate or the corresponding relationship is greater than or less than a preset range, the relay is switched to open-circuiting to stop outputting a current.

### BACKGROUND OF THE INVENTION

### Technical Field of the Invention

The present invention relates to a smart electricity safety detection system for a charging station, and more particularly to one that simultaneously monitors and analyzes a status of an internal circuit of the charging station and a charging status of an electric vehicle, so that when the status of the internal circuit of the charging station and the charging status of the electric vehicle exceed an allowable preset range of the present invention, the charging circuit is disconnected to thereby enhance charging safety of the electric vehicle.

### Description of the Prior Art

Recently, electric vehicle technology has become more and more mature, and more and more users choose electric vehicles to replace traditional gasoline vehicles as their main means of transportation. As a result, the demand for charging stations for fast charging of electric vehicles has become more and more urgent. Electric vehicles are usually charged at high power to shorten the charging time of the electric vehicles, and during the process of charging, if the charging connector of the electric vehicle is not properly connected, or if there is leakage, or if the internal circuit of the charging station or the charging circuit of the electric vehicle is short-circuited due to aging or other causes, continuing the charging operation with high voltage and high current will cause the temperature to rise, leading to accidents such as fire.

Most of the current DC charging stations use multiple comparators to individually compare a single charging/discharging circuit, and are incapable of analyzing a corresponding relationship between first and second charging/discharging circuits at the same time. Therefore, it is very likely that when one of the first and second charging/discharging circuits is at the critical value of the allowable range, the charging station is still charging at high power, but at this time in case that there is a problem with one of the internal circuits of the charging station and the charging circuit inside the electric vehicle, if the charging circuit cannot be disconnected immediately at this time, the accident of the vehicle burning is still likely to occur.

In view of this, the inventor of the present inventor has made research and innovation to create a smart electricity safety detection system for charging stations.

### SUMMARY OF THE INVENTION

An objective of the present invention is to provide a smart electricity safety detection system of a charging station, which comprises: a central processor; a first detection unit, which is operable to detect circuit information of an internal circuit of the charging station and transmits the circuit information to the central processor; a relay, which is connected to a power supply and is in signal connection with the central processor, and is operably switchable by the central processor to open-circuiting or closed-circuiting; an output port, which is connected to an output terminal of the relay for connection with an input port of an electric vehicle for charging; and a second detection unit, which is operable to detect output information of the output port and transmit the output information to the central processor to perform real-time monitoring and analysis of the circuit information and the output information, so that when a corresponding relationship between the circuit information and the output information is greater than or less than a built-in allowable preset range, a signal is triggered to drive the relay to open-circuiting, in order to stop outputting a current.

In the smart electricity safety detection system for the charging station disclosed in the present invention, the first detection unit at least comprises a detection element for detecting voltage, current, or temperature of the internal circuit of the charging station.

In the smart electricity safety detection system for the charging station disclosed in the present invention, the second detection unit at least comprises a detection element for detecting voltage, current, power, or temperature of the output port.

In the smart electricity safety detection system for the charging station disclosed in the present invention, the central processor is connected to a memory unit for storing history of the central processor and an allowable preset range of a change rate or a corresponding relationship of the circuit information and the output information.

The smart electricity safety detection system for the charging station disclosed in the present invention further comprises a communication unit in signal connection with the central processor, wherein the communication unit is operable to connect a back-end at a remote site, and the back-end is operable to retrieve information of the central processor or the memory unit, and transmit a signal to the central processor to switch the relay to open-circuiting or closed-circuiting.

The smart electricity safety detection system for the charging station disclosed in the present invention further comprises a leakage detection unit in signal connection with the central processor, wherein when the leakage detection unit detects a leakage signal, the central processor triggers a signal to drive the relay to open-circuiting.

The smart electricity safety detection system for the charging station disclosed in the present invention possess the following features and advantages:

(1) being capable of monitoring the voltage, current, temperature, power and leakage current of the internal circuit of the charging station and the electric vehicle connected to the output terminal thereof in real time, so as to immediately disconnect the charging circuit when it exceeds the allowable preset range, to thereby improve and protect the user’s electricity safety.

(2) being capable of monitoring the temperature inside the charging station, so as to send a signal to the central processor in case of temperature abnormality, to thereby improve electricity safety.

(3) enabling connectability of the communication unit with the back-end at a remote site so that the management may access the instantaneous use status or history of the charging station through the back-end, or operatively control the charging station to reset, start, or shut down through the back-end, so s to enhance management of the charging station by means of the back-end.

The embodiments of the present invention will become clearer from the following description and the attached drawings.

### BRIEF DESCRIPTION OF THE DRAWINGS

FIG. 1 is a system block flow chart of the present invention.

FIG. 2 is a block flow chart of an application example of the present invention.

FIG. 3 is a schematic view showing a state of application of a charging station according to the present invention.

### DETAILED DESCRIPTION OF THE PREFERRED EMBODIMENTS

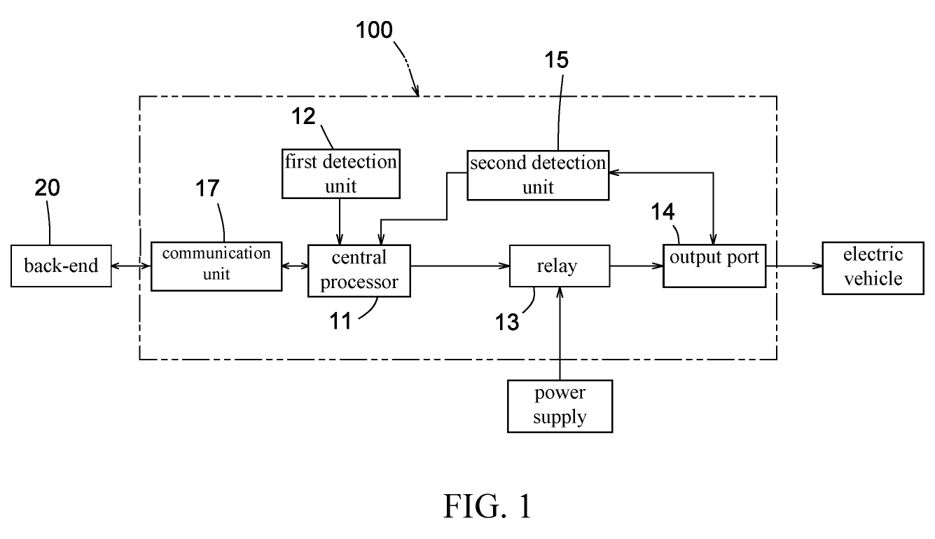

Referring to FIGS. 1-3, the present invention relates to a smart electricity safety detection system for a charging station (100), comprising: a central processor (11); a first detection unit (12), which is operable to detect circuit information of an internal circuit of the charging station and transmit the circuit information to the central processor (11); a relay (13), which is connected to a power supply and is in signal connection with the central processor (11) and is operably switchable to open-circuiting or closed-circuiting by the central processor (11); an output port (14), which is connected to an output terminal of the relay (13) for connection with an input port (not shown) of an electric vehicle to carry out charging; and a second detection unit (15), which is operable to detect output information of the output port (14) and transmit the output information to the central processor (11) for monitoring and analyzing, in real time, a corresponding relationship between the circuit information and the output information, so that when the corresponding relationship between the circuit information and the output information is greater than or less than a built-in allowable preset range, a signal is triggered to drive the relay (13) to open-circuiting to stop outputting a current.

In the smart electricity safety detection system for the charging station (100) disclosed in the present invention, the first and second detection units (12, 15) involve an analog-to-digital conversion unit for conversion of a signal into a digital signal to be then transmitted the central processor (11).

In the smart electricity safety detection system for the charging station (100) disclosed in the present invention, a connector, such as J1772 (Type 1), Mennekes (Type 2), TPC, CCS1, CCS2, or CHAdeMO, is combined with the output port (14), for connection with a charge hole of a corresponding electric vehicle, and the present invention is not limited thereto.

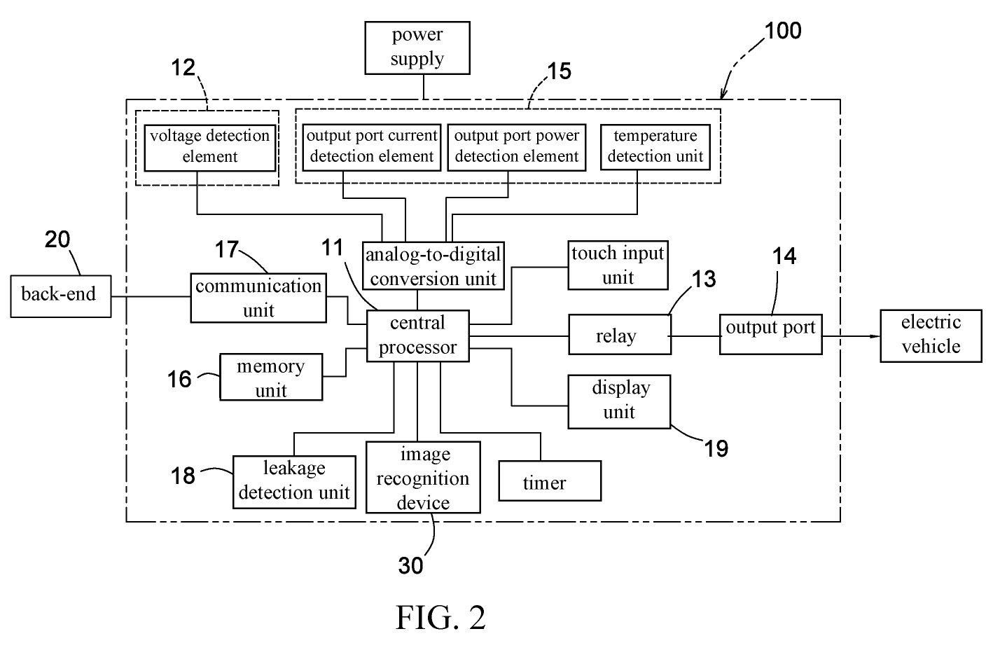

In the smart electricity safety detection system for the charging station (100) disclosed in the present invention, as shown in FIG. 2, the first detection unit (12) at least comprises a detection element for detecting voltage, current, or temperature of the internal circuit of the charging station (100) in order to acquire the circuit information of the internal circuit of the charging station (100), such as voltage, current, and temperature, to be then transmitted to the central processor (11) for interpretation.

In the smart electricity safety detection system for the charging station (100) disclosed in the present invention, the second detection unit (15) at least comprises a detection element for detecting voltage, current, power, or temperature of the output port (14) in order to identify the output information of the output port (14), such as voltage, current, power, or temperature, and to transmit the output information to the central processor for interpretation.

In the smart electricity safety detection system for the charging station disclosed in the present invention, the central processor (11) is connected to a memory unit (16) for storing a charging history of the central processor (11) and a change rate or the allowable preset range of corresponding relationship of the circuit information and the output information.

The smart electricity safety detection system for the charging station disclosed in the present invention further comprises a communication unit (17), which is in signal connection with the central processor (11), and the communication unit (17) is connectable with a back-end (20) at a remote site so that the back-end (20) is operable to retrieve information from the central processor (11) or the memory unit (16), and the back-end (20) is operable to transmit a signal to the central processor (11) to switch the relay to open-circuiting or closed-circuiting. As such, the management that uses the present invention may monitor, at a remote site, a real-time charging status of the charging station (100) or a charging history of each user stored in the memory unit (16), or can have the back-end (20) send an instruction to the central processor (11) to control the relay (13) to switch to open-circuiting or closed- circuiting, that is, the management may remotely reset, start, shut down the charging station (100) without the need to go to the site of the charging station in person, thereby facilitating the management’s operations for management and maintenance.

The smart electricity safety detection system for the charging station disclosed in the present invention further comprises a leakage detection unit (18), which is in signal connection with the central processor (11), so that when the leakage detection unit (18) detects a leakage signal, the central processor (11) triggers a signal to drive the relay to open-circuiting to interrupt performance of a charging operation.

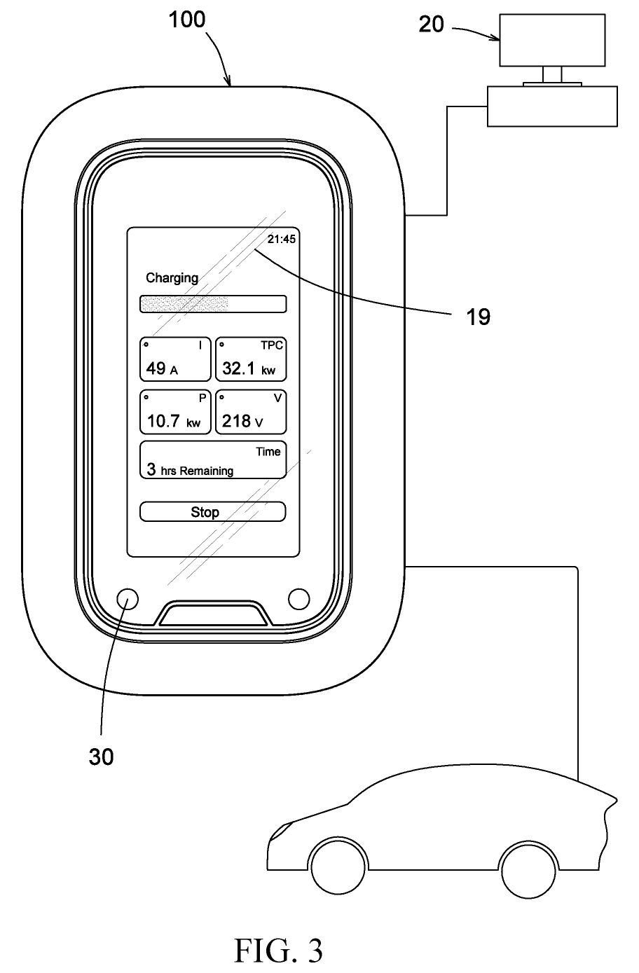

As shown in FIGS. 2 and 3, the smart electricity safety detection system for the charging station disclosed in the present invention further comprises an image recognition device (30), which is in signal connection with the central processor (11) for identifying information, such as vehicle registration and personal information, or for judging whether a vehicle entering the charging site for charging or the surrounding environment of the charging station (100) suffers any abnormality. If it is judged to be abnormal (such as arrears, not parking properly and in designated parking area, and fire), a signal is immediately triggered through the central processor (11) to drive the relay (13) to open-circuiting, in order to stop performance of the charging operation.

As shown in FIGS. 2 and 3, the smart electricity safety detection system for the charging station disclosed in the present invention comprises a display unit (19) for displaying a current charging status, and as shown in FIG. 3, it displays, for an electric vehicle, current remaining power 32.1kw, charging voltage 218V, charging current 49A, and charging power 10.7kw. The display unit (19) can be a touch panel to allow the user to easily touch and select a charging option or input a stop charging instruction via a software interface of the display.

As shown in FIGS. 2 and 3, in the smart electricity safety detection system for the charging station (100) disclosed in the present invention, the central processor (11) being operable for monitoring and analysis of the change rate and the allowable preset range of the corresponding relationship of the first and second detection units (12, 15) refers to a voltage circuit signal of an input terminal of the charging station (100) acquired by the first detection unit (12) being between 170-270V, an output power detected by the second detection unit (15) descending or ascending for more than 20% within 10 seconds, a temperature of the charging station (100) being higher than 80 degrees Celsius, and the like. The value of the allowable preset range used in the present invention can be set according to the usage requirements of different countries or regions, and the present invention is not limited thereto.

In the smart electricity safety detection system for the charging station (100) disclosed in the present invention, the first and second detection units (12) can detect whether the internal circuit of the charging station (100) or a charging circuit of the electric vehicle connected thereto is faulty, and this can be used as a basis for maintenance or cutting of supply of power outage, thereby facilitating management by managers and improving electricity safety.

The smart electricity safety detection system for the charging station disclosed in the present invention firstly uses the first and second detection elements (12, 15) to simultaneously monitor the circuit signal inside the charging station (100) and the output signal of the output port (14) of the charging station (100), and performs comparison and analysis through the central processor (11) to determine whether the use status of the interior circuit of the charging station (100) and the charging circuit of the electric vehicle connected thereto is normal. When an abnormality signal (such as rise of temperature and instant drop of power) occurs, the central processor (11) issues a signal to drive the relay (13) to switch to the open-circuiting position to immediately stop the charging operation of the electric vehicle, so as to maintain the charging safety of the electric vehicle.

In the implementation of the present invention, a corresponding relationship between an available output power of the charging station acquired by the first detection unit (12) (which is the circuit information) and an actual charging output power that the second detection unit (15) supplies to the electric vehicle (which is the output information) cab be set, that is the actual charging output power/the available output power of the charging station is between 95-99%. It is determined to be an abnormality when it exceeds such a range, and the relay is activated to immediately cut off the process of charging. For example, the circuit information acquired by the first detection unit (12) is a source (power company) voltage that is 200V, and the output current is 50A, and the available output power of the charging station is 10KW, and the output information detected and acquired by the second detection unit (15) is the actual charging output power that a charging connector supplies to the electric vehicle connected is actually detected to be 9.8KW, then the actual charging output power/the available output power of the charging station=98%, this being within the allowable range specified in the present invention, and therefore, the charging station maintain normal power supply and does not cut off the circuit. That is, when the incoming voltage of the power company is reduced from the original 220V to 200V, although the actual input power of the electric vehicle connected to the charging connector is 9.8KW, which is much less than the normal 11KW, the present invention will determine that it is due to the voltage reduction of the incoming voltage of the power company, not the problem of the circuit of the charging station or the problem of the charging circuit of the electric vehicle, and allow charging to continue. Of course, such a charging process will not cause any danger.

The smart electricity safety detection system for the charging station disclosed in the present invention can be modified and applied without violating the spirit and scope of the present invention. The present invention is not limited to the above-mentioned embodiments.

I claim:

1. A smart electricity safety detection system for a charging station, comprising:
a central processor;
a first detection unit, which is operable to detect circuit information of an internal circuit of the charging station and transmits the circuit information to the central processor;
a relay, which is connected to a power supply and is in signal connection with the central processor, and is operably switchable by the central processor to open-circuiting or closed-circuiting;
an output port, which is connected to an output terminal of the relay for connection with an input port of an electric vehicle for charging; and
a second detection unit, which is operable to detect output information of the output port and transmit the output information to the central processor to perform real-time monitoring and analysis of the circuit information and the output information, so that when a corresponding relationship between the circuit information and the output information is greater than or less than a built-in allowable preset range, a signal is triggered to drive the relay to open-circuiting, in order to stop outputting a current.

2. The smart electricity safety detection system for the charging station according to claim 1, wherein the first detection unit at least comprises a detection element for detecting voltage, current, or temperature of the internal circuit of the charging station.

3. The smart electricity safety detection system for the charging station according to claim 1, wherein the second detection unit at least comprises a detection element for detecting voltage, current, power, or temperature of the output port.

4. The smart electricity safety detection system for the charging station according to claim 1, wherein the central processor is connected to a memory unit for storing history of the central processor and the allowable preset range of the corresponding relationship between the circuit information and the output information.

5. The smart electricity safety detection system for the charging station according to claim 4, further comprising a communication unit in signal connection with the central processor, wherein the communication unit is operable to connect a back-end at a remote site, and the back-end is operable to retrieve information of the central processor or the memory unit, and transmit a signal to the central processor to switch the relay to open-circuiting or closed-circuiting.

6. The smart electricity safety detection system for the charging station according to claim 1, further comprising a leakage detection unit in signal connection with the central processor, wherein when the leakage detection unit detects a leakage signal, the central processor triggers a signal to drive the relay to open-circuiting.

7. The smart electricity safety detection system for the charging station according to claim 1, further comprising an image recognition device in signal connection with the central processor for identifying information including vehicle registration and personal information of a user, and determining whether a vehicle coming to the charging station for charging or a surrounding environment of the charging station is abnormal, so that when abnormality is identified, a signal is immediately triggered by the central processor to drive the relay to open-circuiting, so as to cut off an operation of charging.
